(19) United States
(12) Patent Application Publication
(10) Pub. No.: US 2013/0181683 A1
(43) Pub. Date: Jul. 18, 2013

(54) Battery Charging Circuit and Reference Signal Generator

(71) Applicants: Hsuan-Kai Wang, New Taipei City (TW); Nien-Hui Kung, Hsinchu City (TW); Chieh-Wei Chen, Taipei City (TW)

(72) Inventors: Hsuan-Kai Wang, New Taipei City (TW); Nien-Hui Kung, Hsinchu City (TW); Chieh-Wei Chen, Taipei City (TW)

(73) Assignee: Richtek Technology Corporation, R.O.C.

(21) Appl. No.: 13/351,917

(22) Filed: Jan. 17, 2012

(51) Int. Cl. H02J 7/00; H03K 3/011

(52) U.S. Cl. 320/150; 327/513

(57) ABSTRACT

The present invention discloses a battery charging circuit adjusting a charging voltage or a charging current according to a battery temperature, which includes: a power stage circuit including at least one power transistor switch and converting input power to charging power by operating the power transistor switch within a temperature range, wherein the charging power includes the charging voltage and the charging current; a reference signal generator obtaining signals representing the battery temperature and generating a reference signal accordingly; and a control circuit generating a switch signal according to the reference signal for operating the power transistor of the power stage circuit, wherein the charging voltage or the charging current is gradually increased as the battery temperature increases in a lower range within the temperature range or gradually decreased as the battery temperature increases in a higher range within the temperature range.

### BACKGROUND OF THE INVENTION

1. Field of Invention

The present invention relates to a battery charging circuit, in particular to such a circuit capable of improving the charging efficiency and maintaining the charging safety.

2. Description of Related Art

Hand-held devices such as mobile phones, digital cameras, and notebook computers usually need a rechargeable battery. When the battery is being charged, electrical energy is converted into chemical energy and thermal energy, and the thermal energy heats the battery. If the charging current is large, the battery temperature rises very quickly. When the charging power is increased, the proportion of the thermal energy converted from the electrical energy is also increased. If the battery temperature is too high, it can damage the battery, such as burning out a Li-ion battery, or even causing it to explode. And if the battery is charged while the battery temperature is low, because the materials inside the battery (such as Li ions) are relatively inactive, a larger charging voltage or a larger charging current may cause damages to the battery. Therefore, the battery needs to be protected during charging in high temperature and low temperature regions.

In general, most of the battery charging systems control the charging current of the battery. When the battery temperature is too high or too low, it decreases the charging current to protect the battery. However, JEITA (Japan Electronics and Information Technology Industries Association) and BAJ (Battery Association of Japan) published a “new specification of charging Li-ion battery”. It specifies that both the charging current (that is, the current supplied to the battery by a charger during a battery charging period) and the charging cutoff voltage (that is, the voltage between two terminals of the battery at the end of the battery charging period) need to be decreased in high and low temperature regions for safety.

FIG. 1A shows conventional arrangement for charging voltage and FIG. 1B shows conventional arrangement for charging current. Within the normal charging temperature range (T2-T3, e.g. 10° C.-45° C.), the Li-ion battery can be charged by an upper limit charging voltage (4.2V) and an upper limit charging current (Ic) according to the suggested optimal numbers by the battery manufacturer. The battery can be charged safely.

Within a low battery temperature range (T2-T1, e.g. 10° C.-0° C.), the charging voltage needs to be dropped to 4.05V and the charging current needs to be dropped to Ic/2. If the temperature is further dropped under T1 (e.g. 0° C.), the system should stop charging the battery. If the temperature of the battery surface is risen above T3, because the cathode materials will become more active and react with electrolytes as the battery voltage increases, the charging voltage should be dropped to 4.05V, and the charging current should be dropped to Ic/2. If the temperature is further risen above T4 (e.g. 60° C.), the system should stop charging the battery.

The aforementioned prior art drops the charging current or the charging voltage to the lowest safety level when the battery is in the high or low temperature regions. Even though it keeps the battery safe during charging, the charging time needs to be prolonged, or the charging cutoff voltage of the battery needs to be decreased. However, in these high and low temperature regions, the battery has different risks at different temperature points, so if the system always charges the battery in the most conservative manner, the performance of the system is downgraded.

In view of above, the present invention overcomes the foregoing drawbacks by providing a battery charging circuit to improve the charging efficiency while still maintaining the charging safety.

### SUMMARY OF THE INVENTION

An objective of the present invention is to provide a battery charging circuit.

Another objective of the present invention is to provide a reference signal generator.

To achieve the foregoing objectives, in one aspect, the present invention provides a battery charging circuit adjusting a charging voltage or a charging current according to a battery temperature, which comprises: a power stage circuit including at least one power transistor switch and converting input power to charging power by operating the power transistor switch within a temperature range, wherein the charging power includes the charging voltage and the charging current; a reference signal generator obtaining signals representing the battery temperature and generating a reference signal accordingly; and a control circuit generating a switch signal according to the reference signal for operating the power transistor of the power stage circuit, wherein the charging voltage or the charging current is gradually increased as the battery temperature increases in a lower range within the temperature range or gradually decreased as the battery temperature increases in a higher range within the temperature range.

In one of the embodiments, the charging voltage or the charging current is monotonously and gradually increased as the battery temperature increases in a lower range within the temperature range or monotonously and gradually decreased as the battery temperature increases in a higher range within the temperature range.

In one of the embodiments, the charging voltage or the charging current is gradually increased in a stepwise manner as the battery temperature increases in a lower range within the temperature range or gradually decreased in a stepwise manner as the battery temperature increases in a higher range within the temperature range.

In one of the embodiments, the reference signal generator includes: a current source generating a main current signal; a lower range adjustment circuit generating a first current signal, wherein the reference signal is the main current signal subtracted by the first signal or a signal converted from the difference between the main current signal and the first signal when the battery temperature is in the lower range; a higher range adjustment circuit generating a second current signal, wherein the reference signal is the main current signal subtracted by the second signal or a signal converted from the difference between the main current signal and the second signal when the battery temperature is at the higher range; and an over temperature range cutoff circuit controlling the reference signal to be at zero level when the battery temperature is out of the temperature range.

In one of the embodiments, the reference signal generator includes: a current source generating a main current signal; a lower range adjustment circuit generating a first current signal when the battery temperature is at the lower range, wherein the reference signal is the main current signal subtracted by the first signal or a signal converted from the difference between the main current signal and the first signal; and an over temperature range cutoff circuit controlling the reference signal to be at zero level when the battery temperature is out of the temperature range.

In one of the embodiments, the reference signal generator includes: a current source generating a main current signal; a higher range adjustment circuit generating a second current signal when the battery temperature is at the higher range, wherein the reference signal is the main current signal subtracted by the second signal or a signal converted from the difference between the main current signal and the second signal; and an over temperature range cutoff circuit controlling the reference signal to be at zero level when the battery temperature is out of the temperature range.

In one of the embodiments, the converted signals are voltage signals.

In another aspect, the present invention provides a reference signal generator generating a reference signal according to a battery temperature, which comprises: a current source generating a main current signal; an adjustment circuit generating a current adjustment signal when the battery temperature is in a lower range or a higher range of a temperature range, wherein the reference signal is the main current signal subtracted by the current adjustment signal or a signal converted from the difference between the main current signal and the current adjustment signal, and wherein the current adjustment signal is gradually decreased as the battery temperature increases in the lower range of the temperature range or gradually increased as the battery temperature increases in the higher range of the temperature range; and an over temperature range cutoff circuit controlling the reference signal to be at zero level when the battery temperature is out of the temperature range.

The objectives, technical details, features, and effects of the present invention will be better understood with regard to the detailed description of the embodiments below, with reference to the drawings.

### BRIEF DESCRIPTION OF THE DRAWINGS

FIG. 1A is a waveform diagram showing a conventional arrangement for charging voltage.

FIG. 1B is a waveform diagram showing a conventional arrangement for charging current.

FIG. 2 shows a battery charging circuit of the present invention.

FIG. 3A is a waveform diagram showing an arrangement for charging voltage according to the present invention.

FIG. 3B is a waveform diagram showing an arrangement for charging current according to the present invention.

FIG. 4 shows a circuit diagram of a reference signal generator of the present invention.

FIG. 5A shows a waveform diagram of an arrangement for charging voltage according to another embodiment of the present invention.

FIG. 5B shows a waveform diagram of an arrangement for charging current according to another embodiment of the present invention.

FIG. 6 shows a circuit diagram of another reference signal generator of the present invention.

FIG. 7A shows a waveform diagram of an arrangement for charging voltage according to another embodiment of the present invention.

FIG. 7B shows a waveform diagram of an arrangement for charging current according to another embodiment of the present invention.

FIG. 8 shows a block diagram of another reference signal generator, illustrating another embodiment of the present invention.

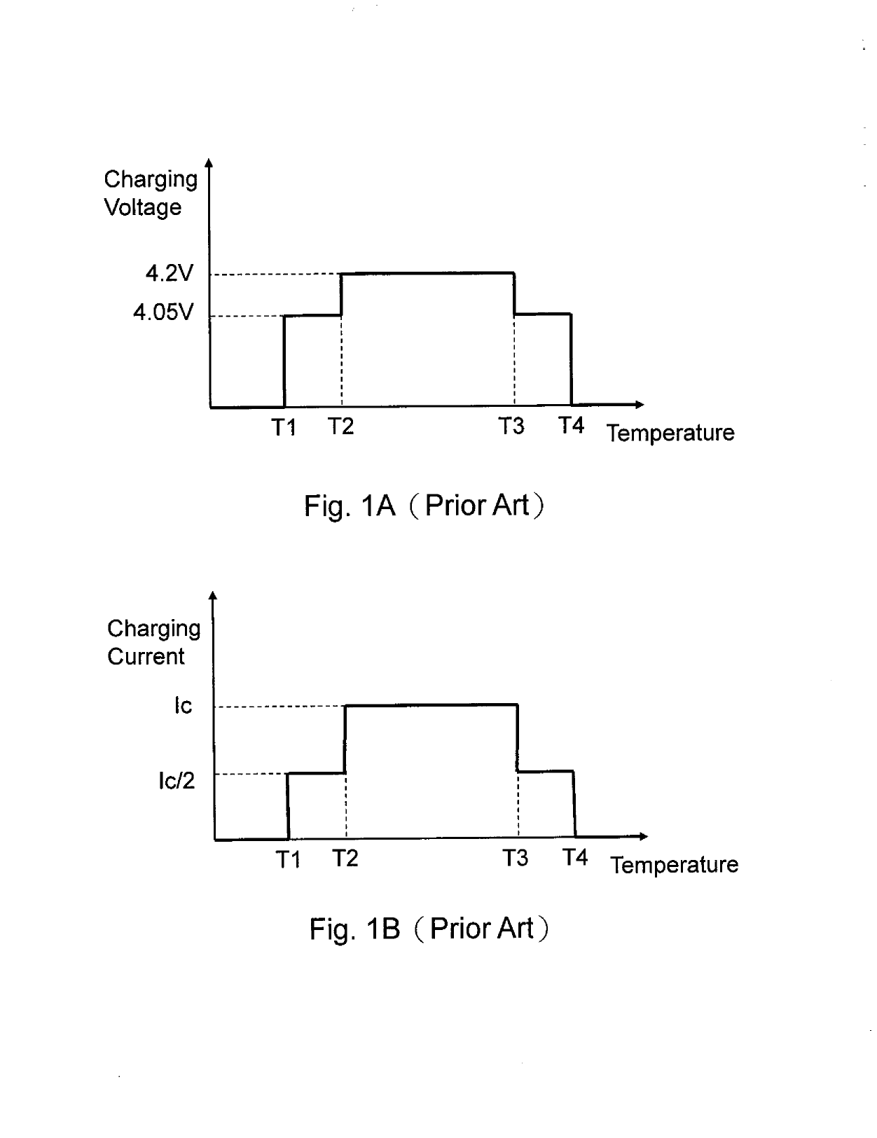

### DESCRIPTION OF THE PREFERRED EMBODIMENTS

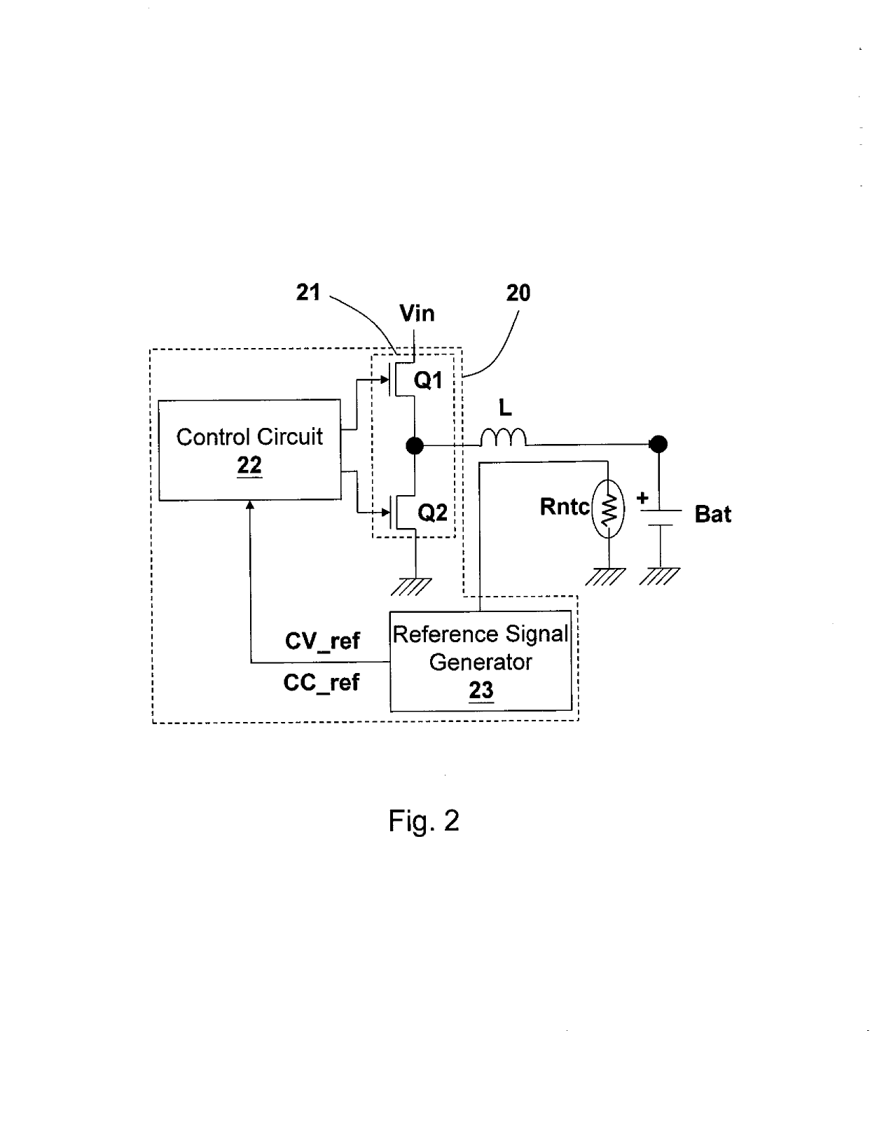

FIG. 2 shows a battery charging circuit of the present invention. The battery charging circuit 20 comprises a power stage circuit 21, a control circuit 22, and a reference signal generator 23. The reference signal generator 23 obtains a signal representing the temperature of a battery Bat. For example, the resistance of a thermal resistor Rntc in the battery Bat can be taken as the signal. In this embodiment, the thermal resistor Rntc is an NTC (Negative Temperature Coefficient) resistor, but the scope of the present invention is not limited to this. When the temperature of the battery Bat rises, the resistance of the thermal resistor Rntc in the battery decreases, so the resistance is an index of the temperature of the battery Bat.

According to the resistance of the thermal resistor Rntc or the voltage across the resistor Rntc, the reference signal generator 23 generates reference signals CV_ref and/or CC_ref. The control circuit 22 receives the reference signals CV_ref and/or CC_ref, and generates at least one switch signal for controlling the power transistor switches (Q1, Q2) of the power stage circuit 21. The power stage circuit 21 and the inductor L convert input power to charging power within a temperature range. The charging power includes a charging voltage and a charging current. In this embodiment, the input power comes from the input voltage Vin.

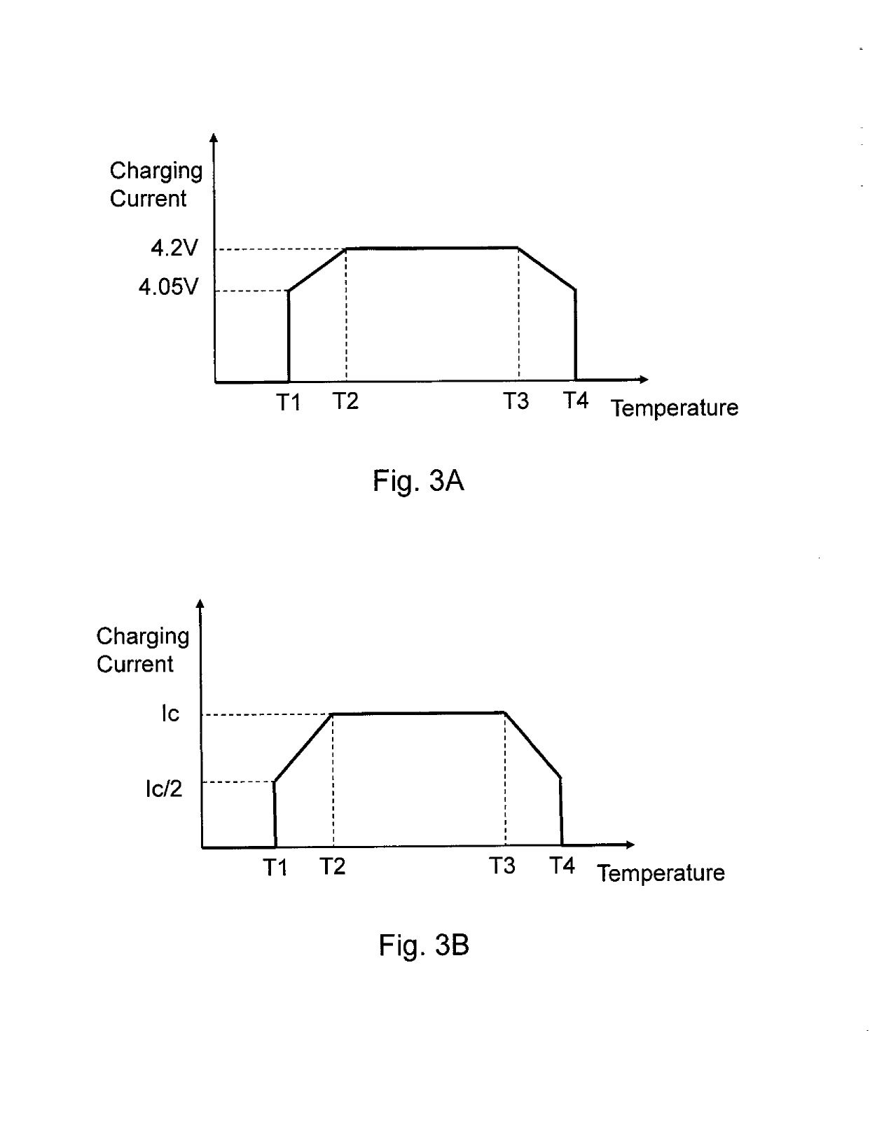

FIGS. 3A and 3B show waveform diagrams of the charging voltage and the charging current of the present invention. Within the normal charging temperature range (T2 to T3, e.g. 10° C.-45° C.), the battery such as a Li-ion battery is charged by an upper limit charging voltage (e.g. 4.2V) and an upper limit charging current (Ic) according to the suggested optimal numbers by the battery manufacturer. The battery is charged safely. Within a low battery temperature range (T2-T1, e.g. 10° C.-0° C.), the charging voltage is decreasingly dropped to a lowest level, e.g. to 4.05V, and the charging current is decreasingly dropped to a lowest level, e.g. to Ic/2. If the temperature further drops under T1 (e.g. 0° C.), the system stops charging the battery. If the temperature of the battery surface rises above T3, because the cathode materials become more active and react with electrolytes when the battery voltage rises, the charging voltage needs to be gradually dropped to a lowest level, e.g. to 4.05V, and the charging current needs to be gradually dropped to a lowest level, e.g. to Ic/2. If the temperature further rises above T4 (e.g. 60° C.), the system stops charging the battery. According to the present invention, in the higher range (T3-T4) within the charging temperature range (between T1 and T4), the charging voltage and/or current is gradually decreasing as the temperature rises and in the lower range (T1-T2) within the charging temperature range, the charging voltage and/or current is gradually increasing as the temperature rises; this embodiment shows the arrangement of monotonous and gradual decreasing (increasing) but the scope of the present invention should cover monotonous and gradual decreasing (increasing) graphs and non-monotonous and gradual decreasing (increasing) graphs. Within the lower range (T1-T2) or the higher range (T3-T4) of the charging temperature range (T1-T4), the embodiment improves the charging efficiency while still maintains the charging safety.

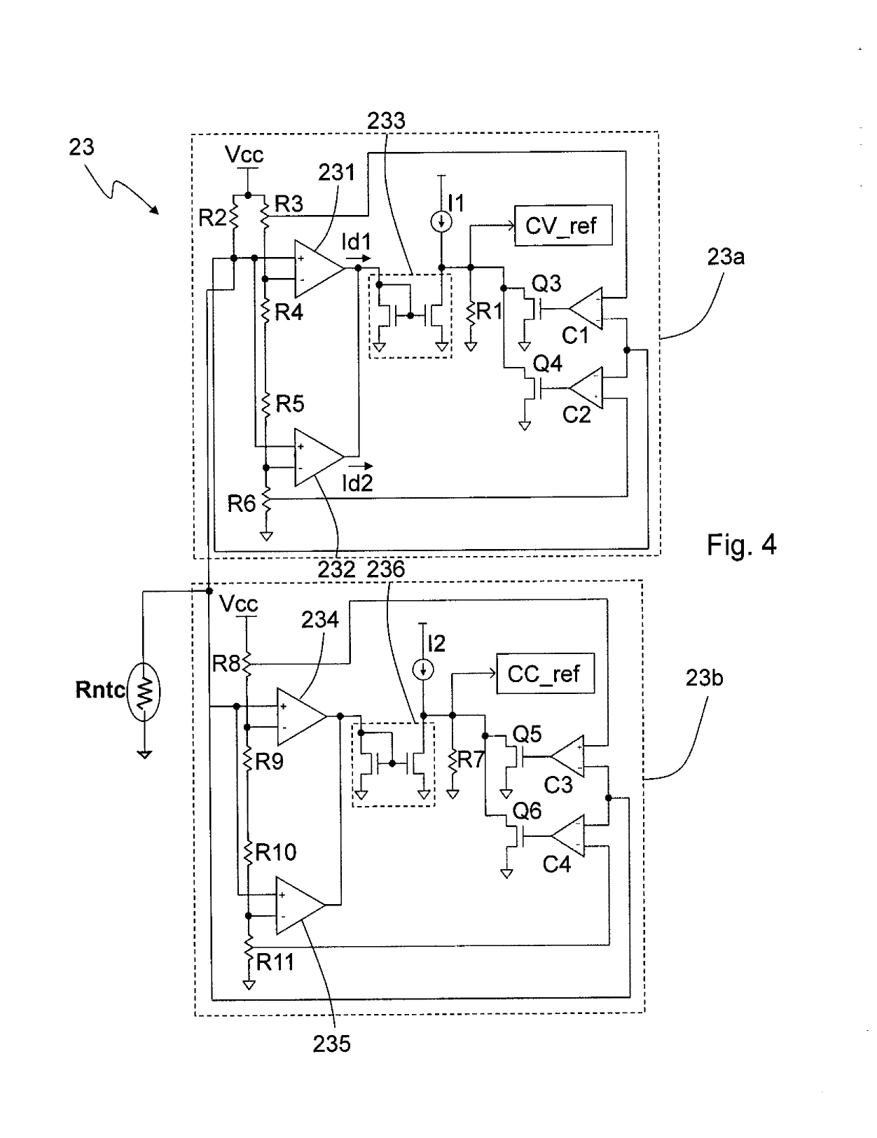

FIG. 4 shows a circuit diagram of the reference signal generator of the present invention. The reference signal generator 23 in this embodiment includes a first reference signal generator 23a and a second reference signal generator 23b which respectively generate reference signals CV_ref and CC_ref. In another embodiment, the reference signal generator 23 can include only one of the two generators, and the other reference signal can be obtained by adjusting the generated reference signal through an adjustment circuit. Such an adjustment circuit maybe integrated into the control circuit 22, and the control circuit 22 transfers one reference signal into two reference signals according to actual requirements. When the battery temperature is in the lower range (T1-T2), the first reference signal generator 23a obtains the voltage across the thermal resistor Rntc. A transconductance amplifier 231 compares the voltage across the thermal resistor Rntc with a reference voltage and obtains their difference (the voltage across the thermal resistor Rntc is larger than the reference voltage because the resistance of the thermal resistor Rntc is larger within the lower range). It outputs a current Id1 to a current mirror 233. The current Id1 is decreased as the temperature increases. The current source I1 generates a current I1. Because the current mirror 233 copies the current Id1, the current through the resistor R1 is (I1−Id1). Thus, the reference signal CV_ref, which is the voltage across the resistor R1, is [(I1−Id1)×R1]. The reference voltage mentioned above can be set by various ways; in this embodiment, it is a voltage obtained from a node of a series circuit of the resistors R3-R6 connected in series. One end of these resistors is connected to a constant or variable voltage Vcc. In addition, the thermal resistor Rntc and a resistor R2 are connected in series to the voltage Vcc.

When the battery temperature is in the normal temperature range (T2-T3), both of the transconductance amplifiers 231 and 232 output zero current (Id1=Id2=0), hence the reference signal CV_ref which is the voltage across the resistor R1 is (I1×R1). When the battery temperature is in the higher range (T3-T4), the first reference signal generator 23a compares the voltage across the thermal resistor Rntc with a reference voltage and obtains their difference. A transconductance amplifier 232 outputs a current Id2 to the current mirror 233. The current Id2 is increased as the temperature increases. The current source I1 generates a current I1. Because the current mirror 233 copies the current Id2, the current through the resistor R1 is (I1−Id2). Thus, the reference signal CV_ref which is the voltage across the resistor R1 is [(I1−Id2)×R1]. Therefore, the waveform of the reference signal CV_ref is similar to the waveform of the charging voltage in FIG. 3A. According to the reference signal CV_ref, the control circuit 22 can control the power stage circuit 21 to generate the required charging voltage.

If the battery temperature is lower than the temperature T1, the comparator C1 outputs a signal to turn on the transistor Q3, such that the reference signal CV_ref is at a zero level. Likely, if the battery temperature is higher than the temperature T4, the comparator C4 outputs a signal to turn on the transistor Q4, such that the reference signal CV_ref is at a zero level.

The second reference signal generator 23b includes transconductance amplifiers (234, 235), resistors R7-R11, a current mirror 236, transistors Q5-Q6, and comparators C3-C4. It generates a reference signal CC_ref as the input of the control circuit 22. Because the configuration of the second reference signal generator 23b is the same as that of the first reference signal generator 23a, the details of such configuration are not redundantly explained again.

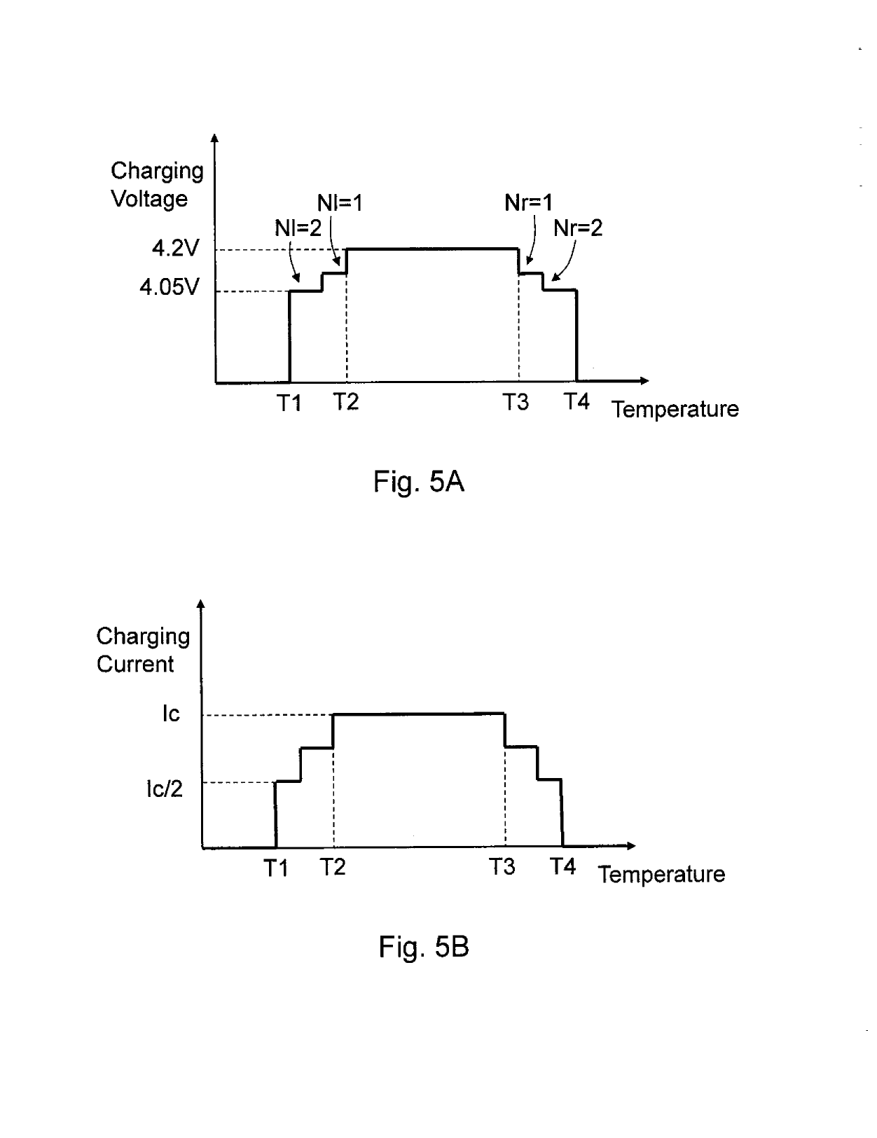

FIGS. 5A and 5B show waveform diagrams of the charging voltage and the charging current according to another embodiment of the present invention. Within the normal charging temperature range (T2 to T3), the Li-ion battery is charged by an upper limit charging voltage (e.g. 4.2V) and an upper limit charging current (Ic) according to the suggested optimal numbers by the battery manufacturer. The battery is charged safely. Within a lower battery temperature range (T2-T1), the charging voltage is gradually decreased (as the temperature decreases) in a stepwise manner, first to 4.14V and next to 4.05V, and the charging current is also gradually decreased (as the temperature decreases) in a stepwise manner, first to (¾)Ic and next to Ic/2. This embodiment shows a two-step arrangement (N1=1, 2 and Nr=1, 2); it is certainly possible to modify it such that more steps are arranged in a gradual decreasing or gradual increasing manner, or only one side (one of the ranges of T1-T2 and T3-T4) is arranged in stepwise gradual decreasing or gradual increasing manner. The present embodiment is an example of non-monotonous increasing (decreasing). If the temperature further drops under T1 (e.g. 0° C.), the system stops charging the battery. If the temperature of the battery surface rises above T3, the charging voltage is dropped to 4.05V in a stepwise manner and the charging current is dropped to Ic/2 in a stepwise manner (by two steps in this embodiment). If the temperature further rises above T4 (e.g. 60° C.), the system stops charging the battery.

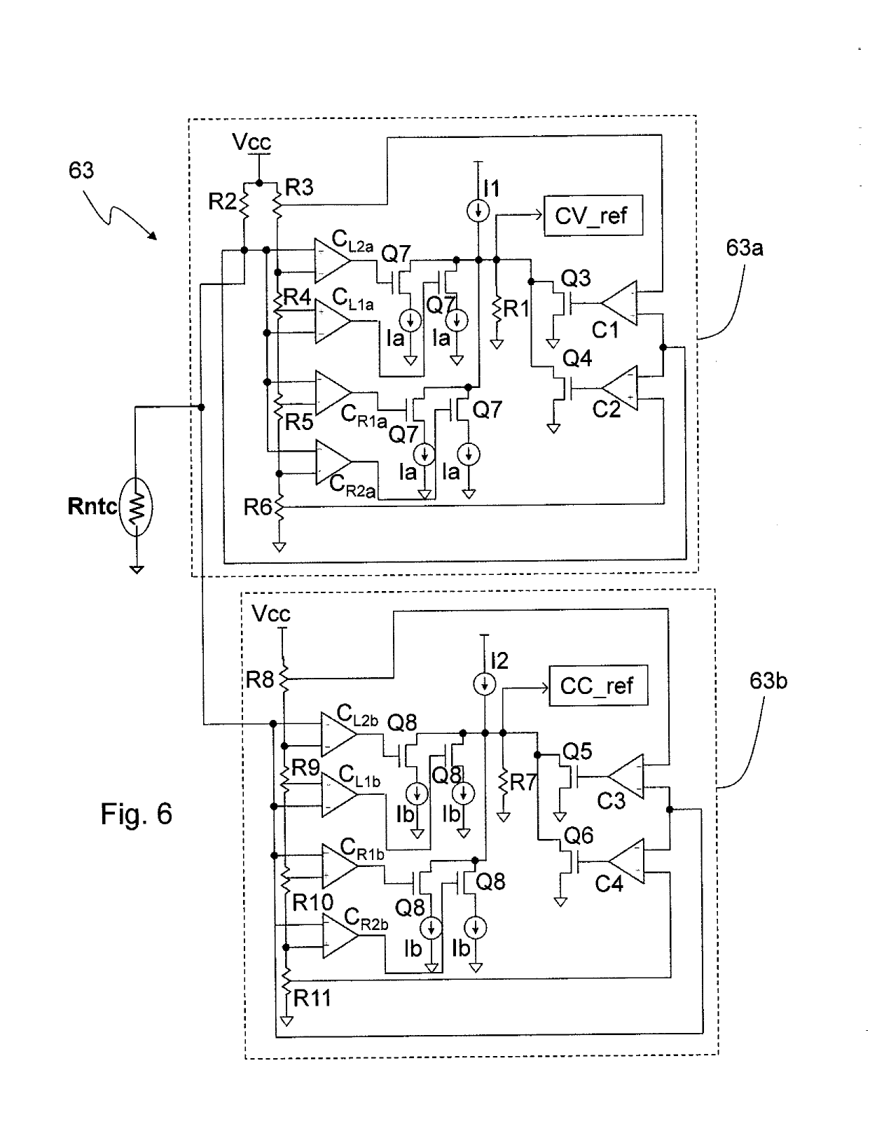

FIG. 6 shows a circuit diagram of the reference signal generator according to another embodiment of the present invention. The reference signal generator 63 in this embodiment includes a first reference signal generator 63a and a second reference signal generator 63b which respectively generate reference signals CV_ref and CC_ref. In another embodiment, the reference signal generator 63 can include only one of the two generators, and the other reference signal can be obtained by adjusting the generated reference signal through an adjustment circuit. Such an adjustment circuit may be integrated into the control circuit 22, and the control circuit 22 transfers one reference signal into two reference signals according to actual requirements. When the battery temperature is in the lower range (T1-T2), the first reference signal generator 63a obtains the voltage across the thermal resistor Rntc. The comparators C_{L2a} and C_{L1a} respectively compare the voltage across the thermal resistor Rntc with corresponding reference voltages and generate output signals to control corresponding transistors Q7. The current source I1 generates a current I1. When the battery temperature is in the lower part between T1 and T2, the two transistors Q7 are both turned on, the two current sources Ia both generate a current Ia. Thus, the current through the resistor R1 is (I1−Ia−Ia). That is, the reference signal Cv_ref is [(I1−2×Ia)×R1] which is the voltage across R1, as shown in FIG. 5A by the segment N1=2.

If the temperature continues to rise, it leaves the range of N1=2, but does not reach T2 yet. The comparator C_{L2a} changes its output state, while the comparator C_{L1a} maintains its output state. Thus, the current through the resistor R1 is (I1−Ia), so the reference signal is [(I1−Ia)×R1] which is the voltage across R1, as shown in FIG. 5A by the segment N1=1.

When the battery temperature is in the normal temperature range (T2-T3), the comparators (C_{L1a}, C_{L2a}, C_{R1a}, and C_{R2a}) do not turn on the transistors Q7, and hence, the reference signal CV_ref is (I1×R1) which is the voltage across R1. When the battery temperature rises above the temperature T3, the comparator C_{R1a} compares the voltage across the thermal resistor Rntc with a reference voltage, and turns on its corresponding transistor Q7. In the meanwhile, the comparator C_{R2a} does not turn on its corresponding transistor Q7. The current source I1 generates a current I1. Thus, the current through the resistor R1 is (I1−Ia). That is, the reference signal Cv_ref is [(I1−Ia)×R1] which is the voltage across R1, as shown in FIG. 5A by the segment Nr=1.

When the battery temperature is in the higher range between T3 and T4, i.e., in the range of Nr=2 in FIG. 5A, the comparators C_{R2a} and C_{R1a} both turn on their corresponding transistors Q7. The current source I1 generates a current I1. Thus, the current through the resistor R1 is (I1−Ia−Ia). That is, the reference signal Cv_ref is [(I1−2×Ia)×R1] which is the voltage across R1, as shown in FIG. 5A by the segment Nr=2.

When the battery temperature is lower than the temperature T1, the comparator C1 outputs a signal to turn on the transistor Q3 such that the reference signal CV_ref is at a zero level. Similarly, when the battery temperature is higher than the temperature T4, the comparator C2 outputs a signal to turn on the transistor Q4 such that the reference signal CV_ref is at a zero level.

The second reference signal generator 63b includes comparators (C_{L1a}, C_{L2a}, C_{R1a}, C_{R2a}), resistors R7-R11, transistors (Q5-Q6, Q8), current sources (I2, Ib) and comparators (C3-C4), and it generates the reference signal CC_ref as the input of the control circuit 22. Because the configuration of the second reference signal generator 63b is the same as that of the first reference signal generator 63a, the details of such configuration are not redundantly explained again.

The reference signal generator of the present invention is not limited to the examples as shown in FIGS. 6 and 4. Any circuit which can generate reference signals to result in the charging voltages and the charging currents as shown by the waveforms in FIGS. 3A, 3B, 5A, 5B, 7A, and 7B, or similar waveforms, should belong to the scope of the present invention.

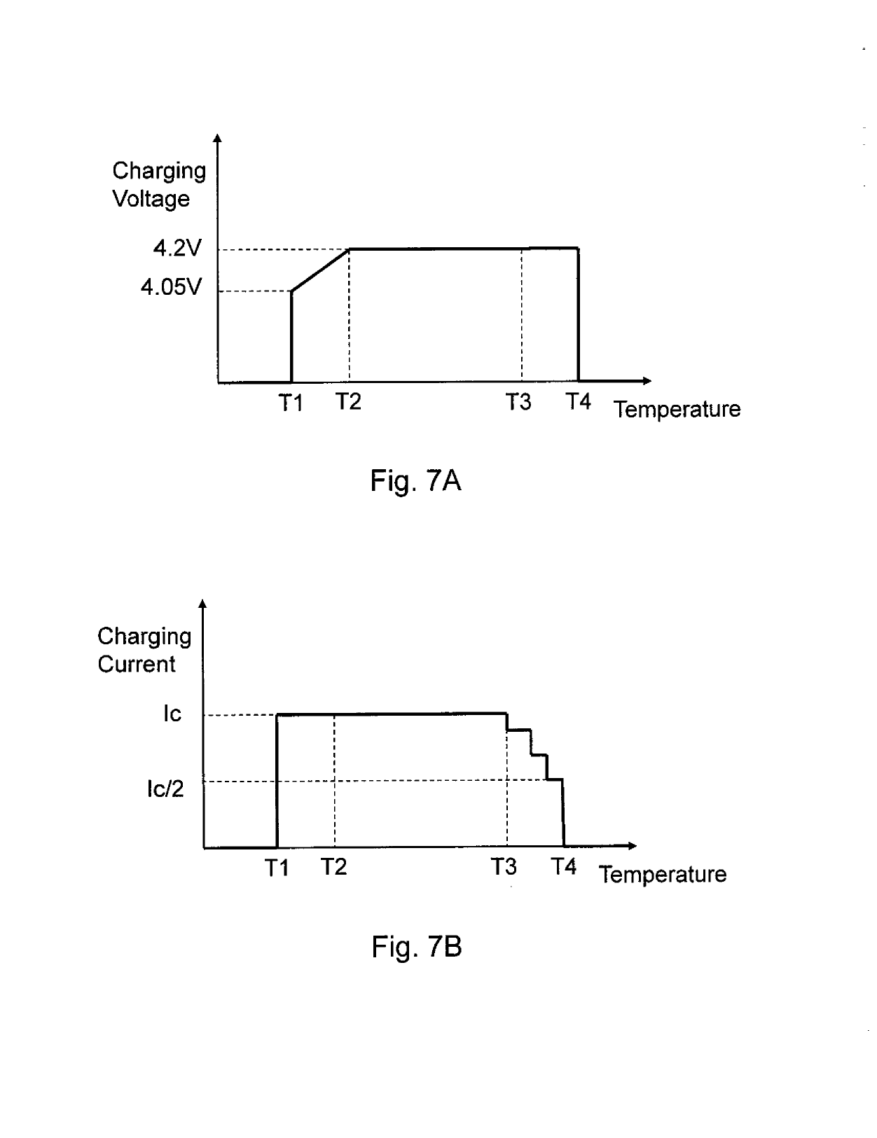

FIG. 7A shows a waveform diagram of the charging voltage according to another embodiment of the present invention. Within the normal charging temperature range (T2 to T3), the Li-ion battery is charged by an upper limit charging voltage (e.g. 4.2V) and an upper limit charging current (Ic) according to the suggested optimal numbers by the battery manufacturer. The battery is charged safely. Within a low battery temperature range (T2-T1), the charging voltage is gradually decreased to 4.05V as the temperature decreases. Within the higher battery temperature range (T3-T4), the battery is still charged by the upper limit (4.2V) of the charging voltage, because the battery materials and operation conditions are different and it is judged that the battery can be charged safely.

FIG. 7B shows a waveform diagram of the charging current according to another embodiment of the present invention. Within the higher battery temperature range (T3-T4), the charging current is decreased to Ic/2 in a three-step manner as the temperature increases. Within the lower battery temperature range (T1-T2), the battery is still charged by the upper limit (4.2V) of the charging voltage, because the battery materials and operation conditions are different and it is judged that the battery can be charged safely.

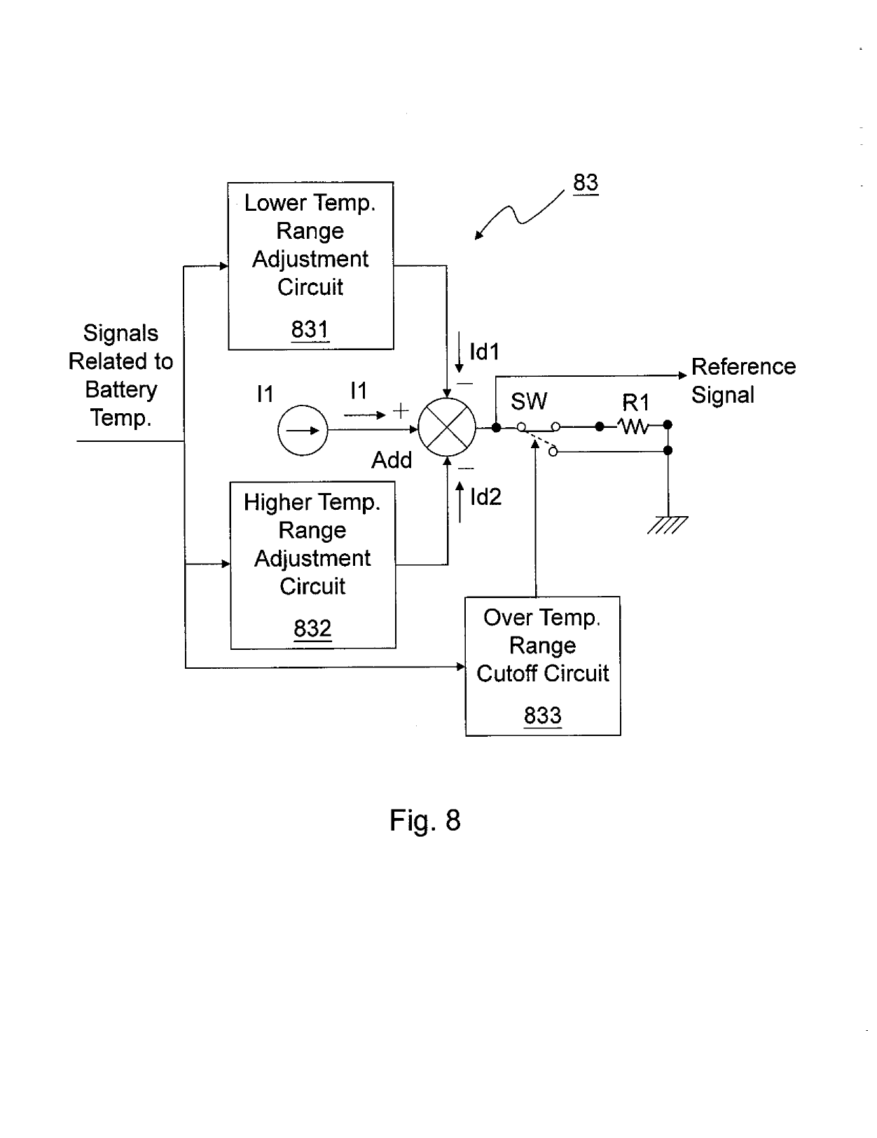

FIG. 8 shows a block diagram of the reference signal generator according to another embodiment of the present invention. The reference signal generator 83 includes a lower range adjustment circuit 831, a higher range adjustment circuit 832, and an over temperature range cutoff circuit 833. The three circuits all receive signals related to the battery temperatures, such as the voltage across the thermal resistor Rntc. When the battery temperature is within the lower range (T1-T2), the lower range adjustment circuit 831 generates a current signal Id1, and the higher range adjustment circuit 832 has no output. The current source I1 generates the current I1. The current I1 is added to minus Id1 through the adder Add. Hence, the current through the switch SW and the resistor R1 is (I1−Id1), and meanwhile, the reference signal is (I1−Id1)×R1. Similarly, when the battery temperature is within the higher range (T3-T4), the higher range adjustment circuit 832 generates a current signal Id2, and meanwhile, the reference signal is (I1−Id2)×R1. When the battery temperature is within the normal temperature range (T2-T3), the current signals Id1 and Id2 are both at a zero level, and the reference signal is I1×R1. The over temperature range cutoff circuit 833 operates when the battery temperature is below T1 or above T4, to switch the connection of the switch SW to ground such that the reference signal is at a zero level.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, in all of the embodiments, a device or circuit which does not affect the major functions of the signals, such as a switch, etc., can be added between two circuits illustrated to be directly connected with each other. The meanings of the high level and low level of a digital signal are interchangeable. For another example, the positive and negative terminals of the amplifiers and comparators are interchangeable, with corresponding amendment to the processing of their output signals. Thus, the present invention should cover all such and other modifications and variations, which should be interpreted to fall within the scope of the following claims and their equivalents.

What is claimed is:

1. A battery charging circuit adjusting a charging voltage or a charging current according to a battery temperature, comprising:
a power stage circuit including at least one power transistor switch and converting input power to charging power by operating the power transistor switch within a temperature range, wherein the charging power includes the charging voltage and the charging current;
a reference signal generator obtaining signals representing the battery temperature and generating a reference signal accordingly;
a feedback circuit generating a feedback signal according to the output voltage; and
a control circuit generating a switch signal according to the reference signal for operating the power transistor of the power stage circuit, wherein the charging voltage or the charging current is gradually increased as the battery temperature increases in a lower range within the temperature range or gradually decreased as the battery temperature increases in a higher range within the temperature range.

2. The battery charging circuit of claim 1, wherein the charging voltage or the charging current is monotonously and gradually increased as the battery temperature increases in a lower range within the temperature range or monotonously and gradually decreased as the battery temperature increases in a higher range within the temperature range.

3. The battery charging circuit of claim 1, wherein the charging voltage or the charging current is gradually increased in a stepwise manner as the battery temperature increases in a lower range within the temperature range or gradually decreased in a stepwise manner as the battery temperature increases in a higher range within the temperature range.

4. The battery charging circuit of claim 1, wherein the reference signal generator includes:
a current source generating a main current signal;
a lower range adjustment circuit generating a first current signal, wherein the reference signal is the main current signal subtracted by the first signal or a signal converted from the difference between the main current signal and the first signal when the battery temperature is in the lower range;
a higher range adjustment circuit generating a second current signal, wherein the reference signal is the main current signal subtracted by the second signal or a signal converted from the difference between the main current signal and the second signal when the battery temperature is at the higher range; and
an over temperature range cutoff circuit controlling the reference signal to be at zero level when the battery temperature is out of the temperature range.

5. The battery charging circuit of claim 4, wherein the signals converted from the differences are voltage signals.

6. The battery charging circuit of claim 1, wherein the reference signal generator includes:
a current source generating a main current signal;
a lower range adjustment circuit generating a first current signal when the battery temperature is at the lower range, wherein the reference signal is the main current signal subtracted by the first signal or a signal converted from the difference between the main current signal and the first signal; and
an over temperature range cutoff circuit controlling the reference signal to be at zero level when the battery temperature is out of the temperature range.

7. The battery charging circuit of claim 6, wherein the signal converted from the difference is a voltage signal.

8. The battery charging circuit of claim 1, wherein the reference signal generator includes:
a current source generating a main current signal;
a higher range adjustment circuit generating a second current signal when the battery temperature is at the higher range, wherein the reference signal is the main current signal subtracted by the second signal or a signal converted from the difference between the main current signal and the second signal; and
an over temperature range cutoff circuit controlling the reference signal to be at zero level when the battery temperature is out of the temperature rang.

9. The battery charging circuit of claim 8, wherein the signal converted from the difference is a voltage signal.

10. A reference signal generator generating a reference signal according to a battery temperature, comprising:
a current source generating a main current signal;
an adjustment circuit generating a current adjustment signal when the battery temperature is in a lower range or a higher range of a temperature range, wherein the reference signal is the main current signal subtracted by the current adjustment signal or a signal converted from the difference between the main current signal and the current adjustment signal, and wherein the current adjustment signal is gradually decreased as the battery temperature increases in the lower range of the temperature range or gradually increased as the battery temperature increases in the higher range of the temperature range; and
an over temperature range cutoff circuit controlling the reference signal to be at zero level when the battery temperature is out of the temperature range.

11. The reference signal generator of claim 10, wherein the current adjustment signal is monotonously and gradually increased or monotonously and gradually decreased.

12. The reference signal generator of claim 10, wherein the current adjustment signal is gradually increased or gradually decreased in a stepwise manner.

13. The reference signal generator of claim 10, wherein the signal converted from the current adjustment signal is a voltage signal.
